(19) United States
(12) Patent Application Publication
(10) Pub. No.: US 2017/0002460 A1
(43) Pub. Date: Jan. 5, 2017

(54) Assembly and Method For Coating Workpieces

(71) Applicant: AMT AG, Doettingen (CH)

(72) Inventors: Silvano Keller, Boettstein (CH); Ralph Herber, Bad Saeckingen (DE)

(21) Appl. No.: 15/189,975

(22) Filed: Jun. 22, 2016

(30) Foreign Application Priority Data
Jul. 3, 2015 (CH) 00969/15

(51) Int. Cl. C23C 16/44; C23C 16/455

(52) U.S. Cl. CPC C23C 16/4412; C23C 16/455

(57) ABSTRACT

The assembly (1) for coating workpieces (32) comprises a treatment chamber (1) with a manipulator (24) arranged therein. The manipulator (24) carries a coating device (25) for coating the workpieces (32). The treatment chamber (1) configured as a tank (1) is topped by an exhaust port (3) for exhausting hot gases and/or coating particles. In the interior of the treatment chamber (1) an exhaust hood (33) for channelizing the gases to be exhausted in the direction of the exhaust port (3) is arranged. The exhaust hood (33) together with the pallet (29) are arranged on a shiftable platform (16). The platform (16) together with the exhaust hood (33) and the pallet (29) can be retracted in and extended from the treatment chamber (1). The exhaust hood (33) is arranged on the platform (16) such that when the platform (16) is positioned retracted the exhaust hood is connected to the exhaust port (3).

### BACKGROUND

The invention relates to an assembly as well as to a method for coating workpieces as set forth in the preamble of claims 1 and 12 respectively. By means of such assemblies workpieces substrates can be coated in a defined atmosphere. One example of such an assembly is cited as a vacuum plasma spray (VPS) system. In such systems the workpieces are coated in a practically evacuated treatment chamber “vacuum chamber” by means of a plasma sprayer. Where necessary, a gas, for instance an inert or reactive gas, adapted to the coating process is ported into the treatment chamber after its evacuation.

To remove the gases introduced into the treatment chamber during coating of a workpiece by the coating jet, the gases in known assemblies are siphoned off from one end of the treatment chamber. Assemblies of this kind have the drawback that the hot gases which constitute a very high thermal stress on the manipulator arranged in the treatment chamber, result in the treatment chamber being additionally soiled by non-applied coating particles, the overspray.

To arrest and/or channelize the overspray it is known to arrange an exhaust hood in the treatment chamber. One such exhaust hood is usually arranged above or behind the pallet. The exhaust hood is especially effective when it is arranged near to the workpieces being coated or even partly enclosing the workpieces. However, an exhaust hood fixedly arranged in the treatment chamber can prove to be a nuisance when componenting the pallet.

Known from EP 1 013 791 A is a generic assembly for a plasma spray system provided with a treatment chamber and a plasma sprayer arranged therein. Arranged vertically below the treatment chamber is a collecting shaft. In the transition zone from the treatment chamber to the collecting shaft a deflector means comprising a plurality of flow deflecting baffles is arranged. The plasma sprayer is arranged in the chamber such that its coating jet is directed downwards against the deflector means. In this assembly the gases are exhausted via the collecting chamber downwards from the treatment chamber whilst the cleaned gases can be returned via a further conduit topping the treatment chamber.

Known from DE 600 03 558 T2 is a device for over-cladding a preform with quartz sand, in subsequent steps an optical fiber being produced from the preform. The device comprises an overcladding apparatus including a plasma chamber. The plasma chamber features an exhaust hood for the removal of hot air and silicic acid vapors. Arranged in the plasma chamber are two plasma torches. The plasma torches serve to render the quartz sand molten which is introduced via a tube injector and fused in the plasma flame. The fused quartz sand is applied to the rotated preform until a prescribed diameter is attained. The plasma chamber is topped by an exhaust hood for exhausting air and silicic acid vapors.

DE 693 07 796 T2 discloses a method and a device for coating substrates by means of plasma spray. The device comprises as evident from in FIG. 2 a spray chamber in which a plasma gun is secured to a robotic arm. The substrate to be coated is arranged on a turntable. To catch the overspray a spray hood is provided which is connected to a dust collector. The spray hood is arranged behind the turntable.

U.S. Pat. No. 2,461,657 A shows a coating apparatus with a rotatable table and an exhaust hood arranged behind the table. A plurality of workpieces can be sited on the table.

Disclosed in DE 10 2004 037 808 A1 is a suction assembly, the hood of which is bolted to a flange.

In conclusion, DE 35 20 924 A1 shows a plasma system with a vacuum tank and a carrier device which can be travelled into and out of the tank.

### SUMMARY

One object of the invention is to create an assembly for coating workpieces generic to the field as cited at the start in which on the one hand the thermal stress on the manipulator as well as the soilage of the manipulator and of the vacuum tank are now maintained minimized whilst, on the other, loading and unloading the pallet is now rendered simple.

Achieving the object is defined by the features as set forth in claim 1. In accordance with the invention an exhaust hood for channelizing the gases to be exhausted in the direction of the exhaust port is arranged in the interior of the treatment chamber, wherein at least the exhaust hood together with the pallet are arranged on a shiftable platform by means of which the exhaust hood together with the pallet can be retracted in and extended from the tank and wherein the exhaust hood is arranged on the platform that when the platform is positioned retracted the exhaust hood is connected to the exhaust port.

The exhaust hood has the effect that the hot gases together with the overspray are now directly ducted to the exhaust port whilst the shiftable platform facilitates componenting and decomponenting the pallet.

Because the gases are now channelized by means of the exhaust hood and directed to the exhaust port the thermal stress on the manipulator as well as soilage of the tank are minimized, resulting in high coating performance being achieved with cost savings. Now that the exhaust hood together with the pallet are arranged on a shiftable platform by means of which the exhaust hood together with the pallet can be extended from and retracted into the tank, componenting and decomponenting the pallet is simplified since the pallet is easier to component with workpieces outside of the tank than within the tank.

In one preferred embodiment the exhaust port is arranged on top of the treatment chamber. Hot gases can now be discharged from the top of the treatment chamber to the advantage of minimizing thermal stress on the manipulator, especially since hot gases in any case have the tendency to rise.

Preferably the exhaust hood is provided with a port facing the coating device. Via this port inflow of the gases into the exhaust hood is achieved.

In another preferred embodiment the exhaust hood is topped by a connecting flange for coupling to the exhaust port. This configuration makes it easy and simple to couple the exhaust hood to the exhaust port.

In a particularly preferred embodiment the pallet is engineered as a turntable provided with means for fixedly locating one or more workpieces, the exhaust hood being arranged non-rotatable on the platform. This now makes it possible to rotate a workpiece affixed to the table in relation to the coating device, the non-rotatable arrangement of the exhaust hood ensuring that the exhaust port is not altered in relation to the coating device.

In yet another preferred embodiment the exhaust hood is arranged in relation to the tank so that the workpiece to be coated is fixable located between the coating device and the inlet port of the exhaust hood or in the exhaust hood behind the inlet port on the table of the pallet. This arrangement achieves that the coating jet during coating of a workpiece is aimed in the direction of the interior of the exhaust hood.

In a further preferred embodiment it is provided for that the table of the pallet is configured to mount a plurality of workpieces which are fixed in place along a circular ring-shaped outer part and that the exhaust hood is arranged non-rotatable and centrally within, respectively above, the circular ring-shaped outer part. This configuration enables a plurality of workpieces to be fixed in place on the table and to be coated one after the other by rotation of the table whilst ensuring that the chamber is directed into the interior of the exhaust hood, since the port thereof does not alter in relation to the coating device.

In another particularly preferred embodiment the treatment chamber is formed by a tank which can be evacuated by means of a vacuum pump. A tank is relatively cost-effective to produce and can easily be adapted to any specific requirements.

In yet a further preferred embodiment one end of the tank is engineered as a door via which the platform can be extended from and retracted into the tank. Such a door makes a large opening via which the platform together with the exhaust hood and the pallet can be moved into and out of the tank.

Preferably the platform is mounted shiftable on a rail for travel in thus making it possible to travel the platform along a prescribed distance, providing a rail constituting a relatively simple and cost-effective solution.

In yet a further particularly preferred embodiment a rail is arranged both within and outside of the treatment chamber, the latter arrangement involving the rail running vertical below the rail running within the treatment chamber and the platform featuring a swiveling mechanism provided with rollers which on extension of the platform from the treatment chamber is swiveled downwards so that the rollers come to rest on the rail arranged outside of the treatment chamber. Since a treatment chamber is usually raised somewhat relative to the shop floor by it standing, for example, on feet, the bottom of the treatment chamber is at a higher level than the shop floor. Where within the treatment chamber and on the shop floor rails are arranged to support or guide the platform, the rails run at different levels. By means of the claimed swiveling mechanism this difference in levels can be compensated and the platform is also able to support itself on the rail running outside of the treatment chamber. This configuration now makes it possible to extend the platform together with the elements arranged thereon, despite the difference in levels, out of the tank and to be supported outside of the treatment chamber. Preferably the swiveling mechanism is engineered such that it is automatically swiveled upon retraction of the platform.

Another object of the invention involves proposing a method for coating workpieces in a treatment chamber as set forth in the preamble of claim 12, by means of which the thermal stress on the manipulator is minimized whilst ensuring good exhaust of the overspray and simplifying componenting and decomponenting the pallet.

In accordance with the invention this is achieved in that for componenting and decomponenting the pallet the platform together with the pallet and the exhaust hood is extended from the treatment chamber whilst the exhaust hood is coupled to the exhaust port when retracting the platform. This thus simplifies componenting and decomponenting the pallet outside of the treatment chamber. In addition, the exhaust hood can accordingly be arranged relatively near to the pallet since the latter has good access when the platform is extended. Since the exhaust hood is coupled to the exhaust port when the platform is retracted, good exhaust of the overspray is also made possible.

Preferably during coating of a workpiece gases are exhausted via the exhaust hood and the exhaust port from the treatment chamber. This enables it to be ensured that the thermal stress on the manipulator is minimized in that the gases together with the overspray are exhausted.

In a particularly preferred embodiment of the method the workpiece to be coated is arranged on the table such that when coating each workpiece the coating jet for coating the workpiece is directed practically horizontal or upwards. This results in a directed gas flow which is particularly of advantage in minimizing soilage of the treatment chamber as well as diminishing the thermal stress on the manipulator.

In another particularly preferred embodiment the exhaust is actioned at the latest on commencement of a coating procedure whereby throughout the complete coating procedure a continual gas flow is generated in the treatment chamber. Since the gas flow is directed from the head of the coating device in the direction of the exhaust port optimum exhaust of any particles of the coating not having been applied is assured.

### DESCRIPTION OF THE FIGURES

The invention will now be discussed in detail with reference to the drawings in which

FIG. 1 is a sectional view through a first example embodiment of the assembly;

FIG. 2 is a further sectional view through the assembly as shown in FIG. 1 with the door of the treatment chamber open;

FIG. 3 is a sectional view through a further example embodiment of the assembly;

FIG. 4 is a magnified view in perspective of parts of the assembly as shown in FIG. 3,

FIG. 5 is a view of the assembly as shown in FIG. 3 during coating.

Like components in the figures are identified by like reference numerals throughout.

### DETAILED DESCRIPTION

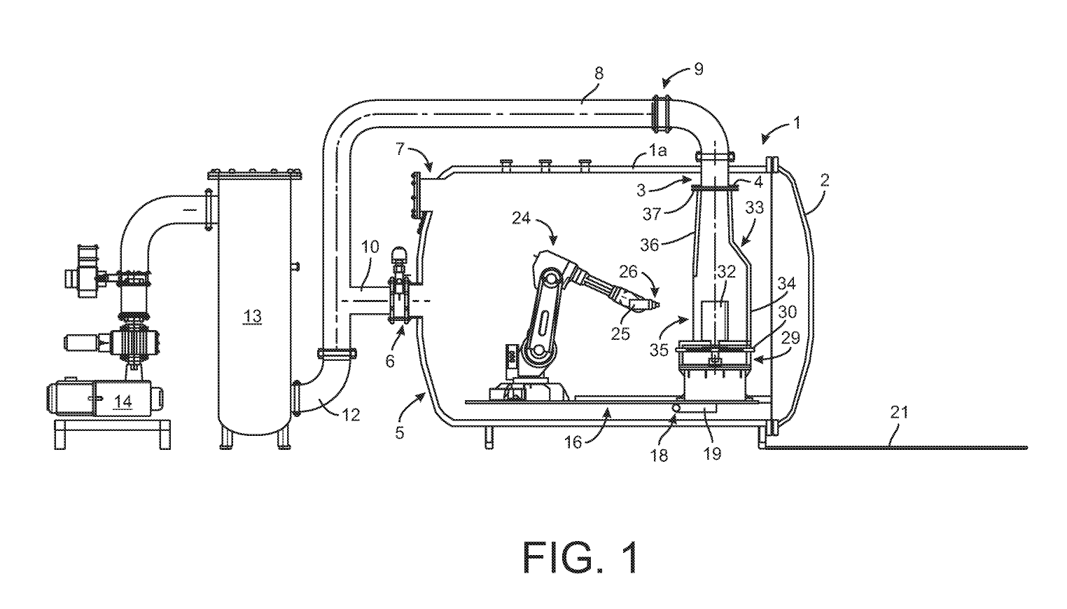

Referring now to FIG. 1 there is illustrated a sectional view through the assembly together with further components depicted diagrammatically. The assembly comprises a treatment chamber 1 in the form of a tank 1a, the one end of which is formed by a door 2. Topping the tank 1a is an exhaust port 3 in the form of a flange 4 in the tank wall. The flange 4 merges via a first exhaust conduit 8 into a conduit 12 which in turn is connected to a filter device 13. Inserted in the second end 5 opposite the door 2 of the tank 1a is a flange 6 which merges via a second exhaust conduit 10 into the conduit 12 connected to the filter device 13. Connected to the filter device 13 is a vacuum pump 14. Included in both the first exhaust conduit 8 as well as in the second exhaust conduit 10 in each case is a shutoff valve 9, 11. The second end 5 of the tank 1a is additionally topped by an additional flange 7 which in this example embodiment has no function but which in an alternative example embodiment may be employed as will be detailed later on.

The assembly features in addition a horizontally travelling platform 16 which can be travelled in and out of the tank 1a. Mounted on this platform 16 are a manipulator 24, a pallet 29 and an exhaust hood 33. The manipulator 24 carries a coating device 25 which is provided with a spray gun 26 generating a coating jet. In this example the coating device 25 is based on being a plasma sprayer. The cables for the power supply and the tubing for handling the plasma gases and the coating procedure are not detailed. The coating device 25 or its spray gun 26 is movable three-dimensionally by means of the manipulator 24 so that workpieces of any shape or surfaces can be coated.

Every mention in this text of an exhaust hood is intended to be understood not just as a hood in the actual sense of the word but the term exhaust hood stands for any kind of means for deflecting, diverting, catching, collecting or channelizing by means of which gases and/or non-applied coating particles—overspray—can be deflected and/or diverted and/or caught and/or collected and/or channelized.

The platform 16 is bottomed by a plurality of rollers running within the tank 1a on a rail as will be detailed later. In the view of FIG. 1 only one of two front rollers 18 is evident which by means of a swivel mechanism 19 sited in the region of the front end of the platform 16 are secured to the platform 16 in such a way that are swivelable on extension of the platform 16 out of the tank 1a downwards level with a rail 21 running before the tank 1a. The swivel mechanism 19 automatically locks into place on extension of the platform from the tank 1a.

Arranged on the platform 16 is a pallet 29 configured in the form of a rotary table 30. Topping the table 30 are fasteners (not shown) for fixing in place one or more workpieces—substrates. In the example as shown, a workpiece 32 is evident centrally fixed in place on the table 30. The exhaust hood 33 is arranged centrally on or above the table 30, the exhaust hood 33 since being arranged non-rotatable does thus not rotate together with the table 30. The exhaust hood 33 partly shrouding the workpiece 32 serves to channelize the coating jet behind the workpiece 32 and upwards in the direction of the exhaust port 3. Within the exhaust hood 33 baffles for deflecting or diverting or catching the coating jet may be provided. The exhaust hood 33 is provided with a port 35 facing the plasma sprayer 25 or the manipulator 24 whilst forming an inlet port for the coating jet. Via this port 35 the coating jet and thus the gases emerging from the spray gun 26 can be streamed into the interior of the exhaust hood 33.

The underpart 34 of the exhaust hood 33 is configured rectangular, three sides of which encompass the workpiece 32 whilst the fourth side forms the port 35. The upper part of the exhaust hood 33 is formed by a tubular projection 36, topped by a flange 37 adapted to the flange 4 of the exhaust port 3. In the retracted condition of the platform 16 as shown, the flange 4 of the exhaust port 3 is in line with the flange 37 of the exhaust hood 33, i.e. the two flanges 4, 37 run coaxially to each other.

In the fully retracted condition of the platform 16 a small gap, for example ranging from approximately 0.5 to 2 mm exists between the two flanges 4, 37. Preferably the two flanges 4, 37 feature a circular ring-shaped end with a circular ring width of a few centimeters so that due to the relatively wide gap and the thereby involved throttling effect hardly any gas intake occurs via this gap. When a minor gap still exists between the two flanges 4, 37 it can be said that exhaust hood 33 is coupled to the exhaust port 3. In any case a coupling between the exhaust hood 33 and exhaust port 3 is to be understood that gases, overspray particles and the like can stream via the exhaust hood 33 into the exhaust port 3 and exhausted from there out of the tank 1a. However, should a tight or tighter seal be wanted between the two flanges 4, 37 there are various options open to a solution. For instance, a heat-resistant elastic seal can be inserted in the end of the one and/or other flanges 4, 37. Alternatively or in addition thereto the platform 16 may be engineered so that once fully retracted it implements a lifting movement resulting in the two flanges 4, 37 coming into touch with each other. Another alternative could involve in the platform 16 being rail-supported within the tank 1a whereby the rail has a slight incline from front to rear, i.e. from the door 2 in the direction of the interior of the tank 1a so that in the retracted condition the platform 16 of the flange 37 of the exhaust hood 33 likewise comes into contact to seal the flange 4 of the exhaust port 3. In conclusion the two ends of the flanges 4, 37 facing each other may also be configured slanting so that they come into contact with each other as soon as the platform 16 is fully retracted. It is understood that the above examples are not to be considered as being conclusive.

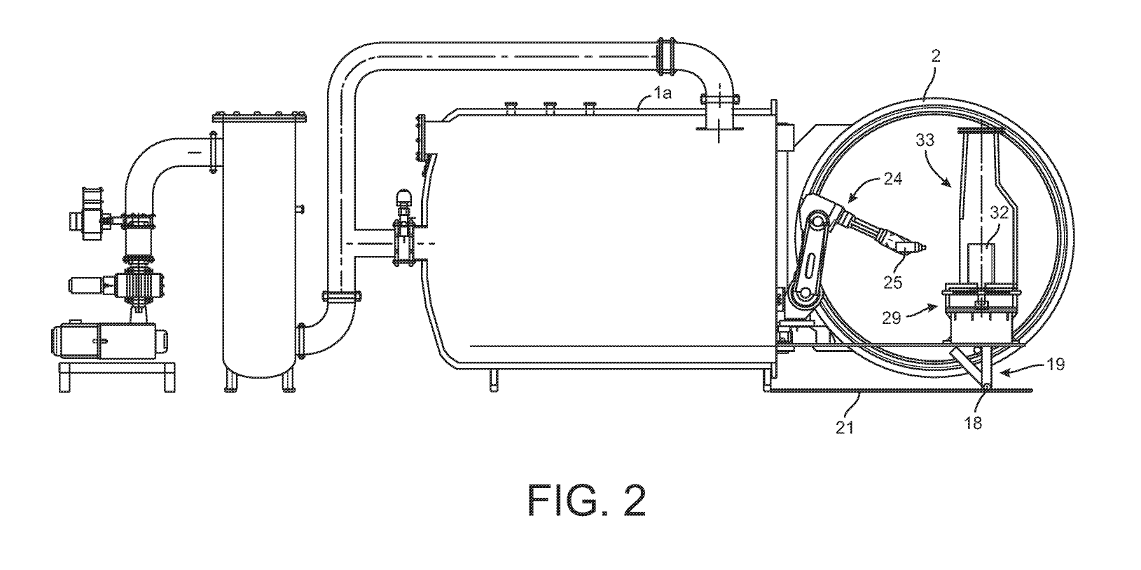

Referring now to FIG. 2 there is illustrated the assembly as shown in FIG. 1 but with the door 2 of the tank 1a now open and the platform 16 together with the elements manipulator 24, coating device 25, pallet 29, workpiece 32, exhaust hood 33 arranged thereon extended from the tank 1a. Evident from this FIG. is that the swivel mechanism 19 carrying the rollers 18 is swiveled down. The rollers 18 are now running on the rail 21 arranged outside of the tank 1a. With the door 2 open and platform 16 extended the workpiece 32 for coating can be secured to the table of the pallet 29 or coated workpieces removed. The rear portion of the platform 16 continues to be supported by the rail within the tank 1a, however. Preferably the swivel mechanism 19 is configured such that it is automatically swiveled up on retraction of the platform 16.

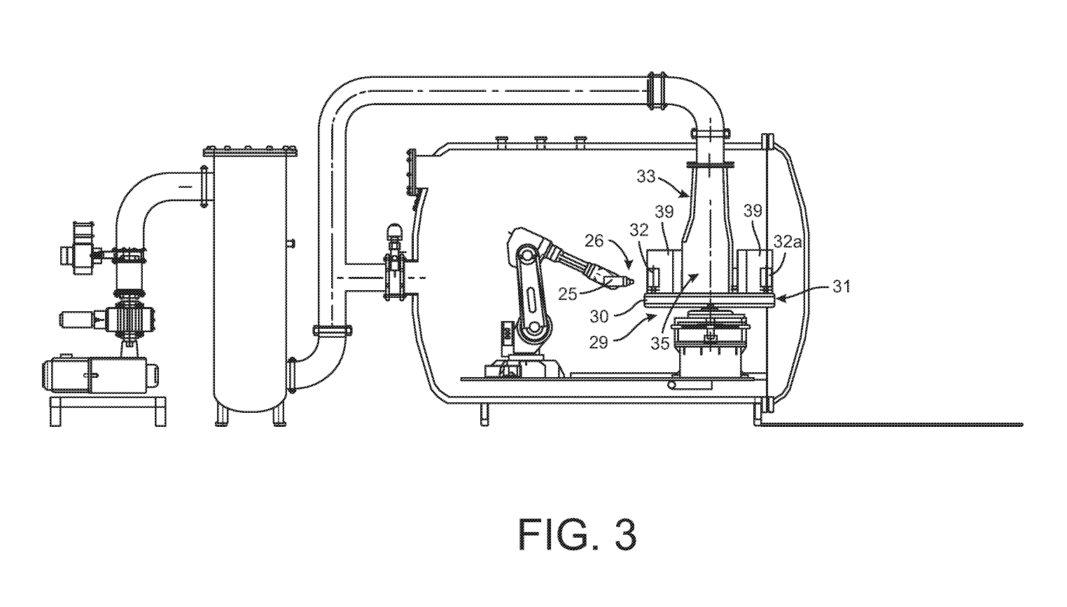

Referring now to FIG. 3 there is illustrated a section through an alternative example embodiment of the assembly. In this example the pallet 29 is formed by a round table 30 provided with a circular ring-shaped outer part 31 configured as a rotor, the outer part 31 being engineered to mount a plurality of workpieces 32, 32a. The table comprises a middle part configured as a stator in which the exhaust hood 33 is arranged. The exhaust hood 33 in turn comprises a port 35 facing the port 35. Via this port gases emerging from the spray gun 26 can stream into the interior of the exhaust hood 33 and exhausted. Disposed between the individual workpieces 32, 32a are baffles 39 as will be detailed later on.

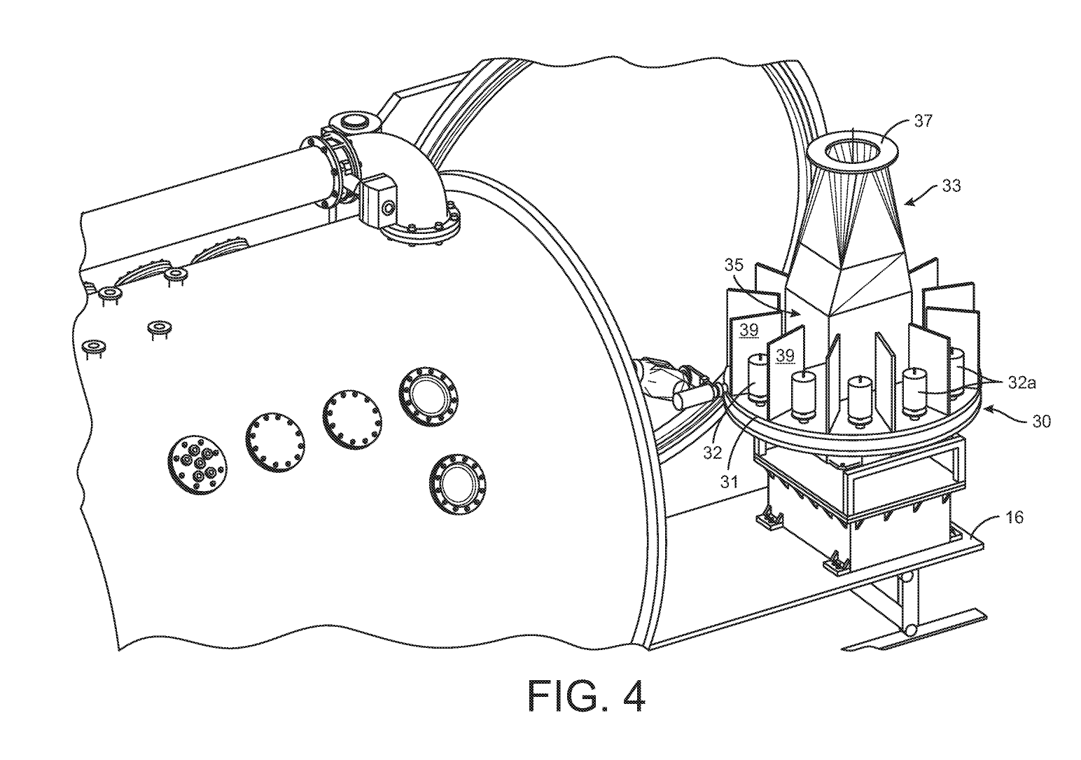

Referring now to FIG. 4 there is illustrated in a magnified view in perspective parts of the assembly as shown in FIG. 3. For this purpose the front part of the platform 16 is shown in the extended condition. Evident in this view is how the workpieces 32, 32a are uniformly evenly distributed on the circular ring-shaped outer part 31 of the table 30. In addition, the baffles 39 are evident which are intended to prevent that the workpiece 32a positioned near to each workpiece 32 being coated inadvertently, namely by deflected powder particles. Due to the two baffles 39 siding each workpiece 32, 32a the coating jet is deflected or channelized in the direction of the port 35 of the exhaust hood 33. The flange 37 topping the exhaust hood 33 together with its wide edge is likewise evident.

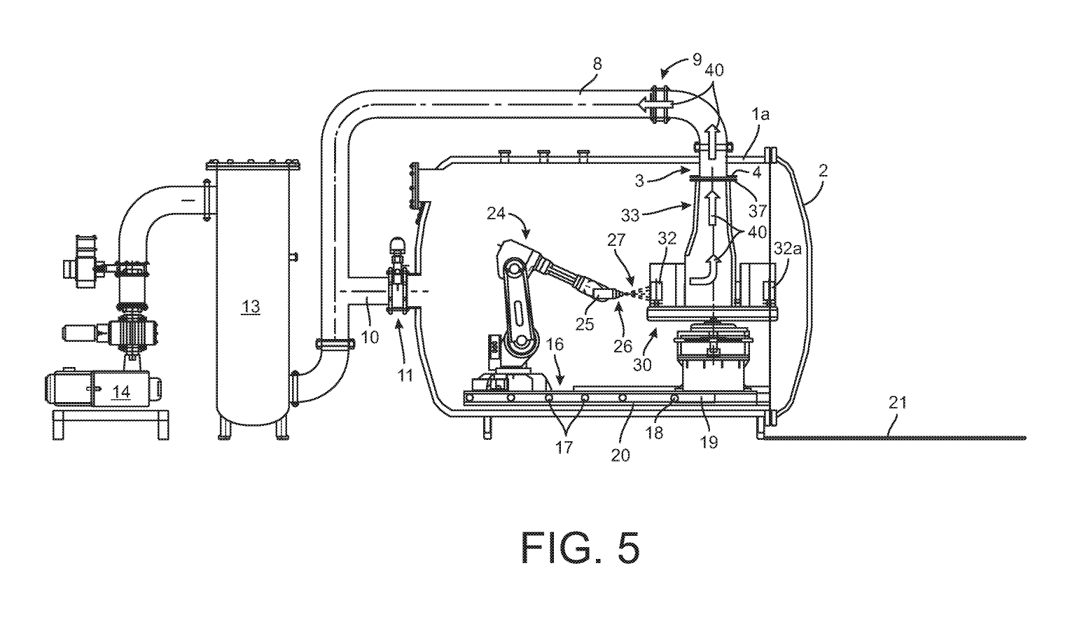

Referring now to FIG. 5 there is illustrated the assembly as shown in FIG. 3 during a coating process. During coating of a workpiece 32 the vacuum pump 14 is in operation so that gases together with any non-applied coating particles are exhausted from the tank 1a via the exhaust hood 33 and the first exhaust conduit 8. Preferably the vacuum pump 14 is switched on at the latest with commencement of the actual coating process so that right from the start, exhausting is active via the exhaust hood 33. For this purpose the shutoff valve 9 arranged in the first exhaust conduit 8 is opened whilst the valve 11 arranged in the second shutoff valve 9 is closed. The coating jet 27 streaming from the spray gun 26 of the coating device 25 is indicated only suggested. The arrows 40 symbolize the stream of gas within the exhaust hood 33. But, in any case, the gases of the coating jet 27 behind the workpiece 32 to be coated are intercepted channelized by the exhaust hood 33 and redirected upwards in the direction of the exhaust port 3.

To minimize soilage of the tank 1a care is taken in the coating process that the coating jet 27 is directed as near horizontal as possible or, if needed, lightly directed upwards so that the gases together with the overspray gain access directly to the exhaust hood 33. To achieve this benefit the workpieces 32, 32a to be coated are arranged on the table 30 of the pallet such that coating is made possible with just a single coating jet 27 directed horizontal or lightly upwards. It will be appreciated that the control of the manipulator 24 is correspondingly adapted.

In this view a plurality of rollers 17 is also evident by means of which the platform 16 is supported travelling on a rail 20 within the tank 1a. Since the rail 21 arranged before the tank 1a runs beneath the rail 20 arranged in the tank 1a the two leading rollers 18 are secured to the platform 16 in the way as described in the previous operation by means of the swivel mechanism 19, the platform 16 in this view being shown in the retracted condition.

Coating with the assembly as shown is sequenced for example as follows: In the extended condition of the platform 16 (FIG. 2) at least one workpiece 32 to be coated is secured to the table 30 of the pallet 29 after which the platform 16 is retracted into the treatment chamber 1 which can be actioned manually or for example by means of an electric motor. On retraction of the platform 16 the flange 37 of the exhaust hood 33 is advanced to the flange 4 of the exhaust port 3 so that the two flanges 4, 37 are lined up coaxially in joining the exhaust hood 33 to the exhaust port 3. After this, the door 2 of the tank 1a is closed (FIG. 1) and the tank la evacuated by means of the vacuum pump 14. Evacuating can be done via the first and/or second exhaust conduit 8, 10 as dictated by means of the two shutoff valves 9, 11. As soon as a specified vacuum is attained in the tank 1a, for example 1 mbar, a gas, for example an inert gas such as argon is streamed into the tank 1a until a maximum pressure of for example 50 mbar is reached. The means needed to feed such an inert gas are not shown. Before the actual coating process the workpiece 32 may be heated which may be done for example by means of the coating device 25 in making use of the jet-plasma jet-. It is understood that no coating powder is streamed as long as the workpiece 32 is being heated up.

Once the workpiece 32 has been heated up a coating process can be started by the coating material, streamed preferably as a powder, is melted by the coating device 25 and applied to the workpiece 32 by means of a coating jet. During the coating process, gases are exhausted from the tank 1a via the exhaust port 3 and the first exhaust conduit 8. For this purpose the exhaust hood 33 is positioned and configured such that the coating jet which usually leaves the coating device 25 in roughly a horizontal direction is deflected upwards in the direction of the exhaust port 3, resulting in an upwards stream of, in addition to the coating gases, also coating particles not applied to the workpiece—the overspray. But in any case as long as coating is going on a stream of gas is maintained by continual exhaust via the exhaust port 3.

In summary it can be emphasized that by means of the assembly as shown overspray particles including the very hot gases are “collected” directly at the workpiece 32 and deflected upwards where they are exhausted via the exhaust port 3 from the tank 1a.

The exhausted overspray particles then stream together with the hot gases via the exhaust conduit 8 into the filter device 13 which filters out the overspray particles, where necessary by means of a plurality of filters, for example by means of a coarse and a downstream fine filter. It is in this way that the majority of the overspray particles including the dust as well as the hot gases are kept away from the manipulator 24, as a result of which higher performance over longer periods of time are achieved in running the manipulator 24. Another advantage is that the tank 1a together with the manipulator 24 and further elements platform 16, coating device 25, table 30 are subjected to less soilage during a coating procedure. Although the exhaust hood 33 is arranged very near or central to the pallet, the pallet in the extended position of the platform is freely accessible, making it simple and easy to quickly component the pallet with the workpieces to be coated.

It is understood that the example embodiment as described above with reference to the drawings is not at all to be considered as being conclusive, but instead a wealth of different configurations is possible, all within the scope of the extent as defined in the patent claims. Thus, for example, baffles may be included within the exhaust hood which deflect the coating jet upwards in the direction of the exhaust port. Where necessary, in an alternative example embodiment only one extended condition may be provided, for example. Another alternative may involve, for example, not including the exhaust port in the tank 1a but within the tank 1a and an extended condition leading within the tank 1a to the additional flange 7 (FIG. 1) topping the second end 5 of the tank 1a. This additional flange 7 would then be connected to the filter device via a conduit. Depending on the configuration and arrangement of the pallet 29 and respectively the table 30 the exhaust hood 33 could also be arranged on the door 2. Instead of an exhaust hood having a rectangular underpart, the latter could also be configured round. A round underpart is preferably configured such that it encompasses the workpiece preferably at least by 180° more preferably by approx. 270° whilst the workpiece in the rectangular design of the exhaust hood is enclosed by it on preferably three sides. The pallet could, for example, also be configured in the form of a linear satellite.

1. An assembly for coating workpieces comprising a treatment chamber in which a pallet and a manipulator carrying the coating device are arranged, the treatment chamber comprising an exhaust port for exhausting hot gases and/or coating particles, and wherein an exhaust hood for channelizing the gases to be exhausted in the direction of the exhaust port is arranged in the interior of the treatment chamber, characterized in that at least the exhaust hood together with the pallet are arranged on a shiftable platform by means of which the exhaust hood together with the pallet can be retracted into and extended from the treatment chamber and wherein the exhaust hood is arranged on the platform that when the platform is positioned retracted the exhaust hood is connected to the exhaust port.

2. The assembly as set forth in claim 1, characterized in that the exhaust port tops the treatment chamber.

3. The assembly as set forth in claim 1, characterized in that the exhaust hood is provided with a port facing the coating device.

4. The assembly as set forth in claim 1, characterized in that the exhaust hood is topped by a flange provided for coupling to the exhaust port.

5. The assembly as set forth in claim 1, characterized in that the pallet is configured as a rotatable table and comprises means for affixing one or more workpiece, and that the exhaust hood is arranged non-rotatable on the platform.

6. The assembly as set forth in claim 5, characterized in that the exhaust hood is arranged relative to the table such that the workpiece to be coated is affixable between the coating device and the inlet port of the exhaust hood or in the exhaust hood behind the port on the table.

7. The assembly as set forth in claim 5, characterized in that the table is configured to mount a plurality of workpieces which are fixed in place along a circular ring-shaped outer part and that the exhaust hood is arranged non-rotatable and centrally within respectively above the circular ring-shaped outer part.

8. The assembly as set forth in claim 1, characterized in that the treatment chamber is formed by a tank which can be evacuated by means of a vacuum pump.

9. The assembly as set forth in claim 1, characterized in that one end of the tank is engineered as a door via which the platform can be extended from and retracted into the tank.

10. The assembly as set forth in claim 1, characterized in that the platform is mounted shiftable on a rail.

11. The assembly as set forth in claim 10, characterized in that a rail is arranged both within and outside of the treatment chamber, the latter arrangement involving the rail running vertical below the rail running within the treatment chamber and the platform featuring a swiveling mechanism provided with rollers which on extension of the platform from the treatment chamber is swiveled downwards so that the rollers come to rest on the rail arranged outside of the treatment chamber.

12. A method for coating workpieces in a treatment chamber in which a manipulator and a pallet for affixedly mounting one or more workpieces to be coated are arranged, the manipulator carrying a coating device for coating the workpieces and the treatment chamber comprises at least one exhaust port for exhausting hot gases and/or coating particles and wherein in the interior of the treatment chamber an exhaust hood is arranged for channelizing the gas to be exhausted in the direction of the exhaust port, and wherein at least the exhaust hood together with the pallet are arranged on a shiftable platform, characterized in that the platform together with the pallet and the exhaust hood are extended from the treatment chamber, after which a workpiece or a plurality of workpieces is/are secured to the pallet, the platform then being retracted together with the pallet and the exhaust hood into the treatment chamber until the exhaust hood is coupled to the exhaust port.

13. The method as set forth in claim 12, characterized in that during coating of a workpiece gases are exhausted via the exhaust hood and the exhaust port from the treatment chamber.

14. The method as set forth in claim 13 wherein the pallet is configured as a rotatable table, characterized in that the workpiece to be coated is arranged on the table such that when coating each workpiece the coating jet for coating the workpiece is directed practically horizontal or upwards.

15. The method as set forth in claim 13, characterized in that the exhaust is actioned at the latest on commencement of a coating procedure whereby throughout the complete coating procedure a continual gas flow is generated in the treatment chamber directed from the head of the coating device upwards in the direction of the exhaust port.

16. The assembly as set forth in claim 2, characterized in that the exhaust hood is provided with a port facing the coating device.

17. The assembly as set forth in claim 6, characterized in that the table is configured to mount a plurality of workpieces which are fixed in place along a circular ring-shaped outer part and that the exhaust hood is arranged non-rotatable and centrally within respectively above the circular ring-shaped outer part.

18. The method as set forth in claim 14, characterized in that the exhaust is actioned at the latest on commencement of a coating procedure whereby throughout the complete coating procedure a continual gas flow is generated in the treatment chamber directed from the head of the coating device upwards in the direction of the exhaust port.
